(19) United States
(12) Patent Application Publication
(10) Pub. No.: US 2014/0251416 A1
(43) Pub. Date: Sep. 11, 2014

(54) FLEXIBLE FRAME FOR SOLAR CELL MODULE APPARATUS AND SOLAR CELL MODULE APPARATUS USING THE SAME

(71) Applicant: Dong Keun Lee, Seoul (KR)

(72) Inventor: Dong Keun Lee, Seoul (KR)

(73) Assignee: LG INNOTEK CO., LTD., Seoul (KR)

(21) Appl. No.: 14/352,814

(22) PCT Filed: Jun. 15, 2012
(86) PCT No.: PCT/KR2012/004750

§ 371 Date: Apr. 18, 2014

(30) Foreign Application Priority Data
Oct. 18, 2011 (KR) 10-2011-0106372

(51) Int. Cl. H01L 31/042

(52) U.S. Cl. CPC H01L 31/0424
USPC 136/251; 52/656.1

(57) ABSTRACT

Disclosed are a flexible frame for a solar cell module and a solar cell apparatus using the same. The flexible frame includes a first support part, a second support part extending inwardly from one end of the first support part, a third support part extending inwardly from an opposite end of the first support part, and an insertion groove defined by the first to third support parts to receive the solar cell module. A width of the insertion groove is narrowed in a direction away from the first support part.

### TECHNICAL FIELD

The embodiment relates to a flexible frame for a solar cell module and a solar cell apparatus using the same.

### BACKGROUND ART

Solar cells may be defined as devices to convert light energy into electrical energy by using a photovoltaic effect of generating electrons when light is incident onto a P-N junction diode. The solar cells may be classified into a silicon solar cell, a compound semiconductor solar cell mainly including a group I-III-VI compound or a group III-V compound, a dye-sensitized solar cell, and an organic solar cell according to materials constituting the junction diode.

The minimum unit of the solar cell is a cell. In general, one cell generates a very small voltage of about 0.5V to about 0.6V. Therefore, a panel-shape structure of connecting a plurality of cells to each other in series on a substrate to generate voltages in a range of several voltages V to several hundreds of voltages V is referred to as a module, and a structure having several modules installed in a frame is referred to as a solar cell apparatus.

Typically, the solar cell apparatus has a structure of glass/filling material (ethylene vinyl acetate, EVA)/solar cell module/filling material (EVA)/surface material (back sheet).

In general, the glass includes low-iron tempered glass. The glass must represent high light transmittance and be treated to reduce the surface reflection loss of incident light. The EVA used as the filling material is interposed between the front/rear side of the solar cell and the back sheet to protect a fragile solar cell device. When the EVA is exposed to UV light for a long time, the EVA may be discolored, and the moisture proof performance of the EVA may be degraded. Accordingly, when the module is fabricated, it is important to select a process suitable for the characteristic of the EVA sheet so that the life span of the module can be increased, and the reliability of the module can be ensured. The back sheet is placed on a rear side of the solar cell module. The back sheet must represent superior adhesive strength between layers, must be easily handled, and must protect the solar cell device from an external environment.

The solar cell apparatus must have resistance against external moisture (H₂O) or external oxygen (O₂), and the problem related to the reliability must be solved in order to improve the performance of the solar cell. According to the related art, in order to solve the problem, a sealing treatment is performed with respect to the lateral side of the solar cell module before the frame is installed, and the frame is installed. However, according to the above scheme, the coating of the sealing agent is required, and moisture may be infiltrated through air holes formed when the sealing agent is coated on the frame.

### DISCLOSURE OF INVENTION

### Technical Problem

The embodiment provides a flexible frame for a solar cell module, which can be fabricated through a simple process and can be improved in terms of the reliability and stability, and a flameless solar cell apparatus by using the same.

### Solution to Problem

According to the embodiment, there is provided a flexible frame for a solar cell module. The flexible frame includes a first support part, a second support part extending inwardly from one end of the first support part, a third support part extending inwardly from an opposite end of the first support part, and an insertion groove defined by the first to third support parts to receive the solar cell module. A width of the insertion groove is narrowed in a direction away from the first support part.

According to the embodiment, there is provided a solar cell apparatus including a solar cell module and an insertion groove having an opening through which the solar cell module is introduced.

### Advantageous Effects of Invention

As described above, the flexible frame for the solar cell module according to the embodiment is formed in a band type by using elastic material, so that the flexible frame can be simply coupled with the solar cell module, and the delamination of the flexible frame can be prevented after the flexible frame has been coupled with the solar cell module. Accordingly, the infiltration of moisture (H₂O) or oxygen (O₂) into the solar cell module can be more minimized.

In addition, the solar cell apparatus according to the embodiment fabricated using the flexible frame does not require a process of coating a sealing agent, so that the manufacturing process for the solar cell apparatus can be simplified, and the manufacturing cost can be reduced. In addition, according to the solar cell apparatus of the embodiment, since the flexible frame can perform a frame function as well as a function of a sealing agent, an additional frame is not required. Therefore, the structure of the solar cell apparatus can be simplified, and the weight thereof can be more reduced.

### BRIEF DESCRIPTION OF DRAWINGS

FIG. 1 is a sectional view showing a flexible frame for a solar cell module according to the embodiment;

FIG. 2 is a perspective view showing a solar cell apparatus according to the embodiment; and

FIG. 3 is a sectional view showing the solar cell apparatus according to the embodiment.

### MODE FOR THE INVENTION

In the description of the embodiments, it will be understood that when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

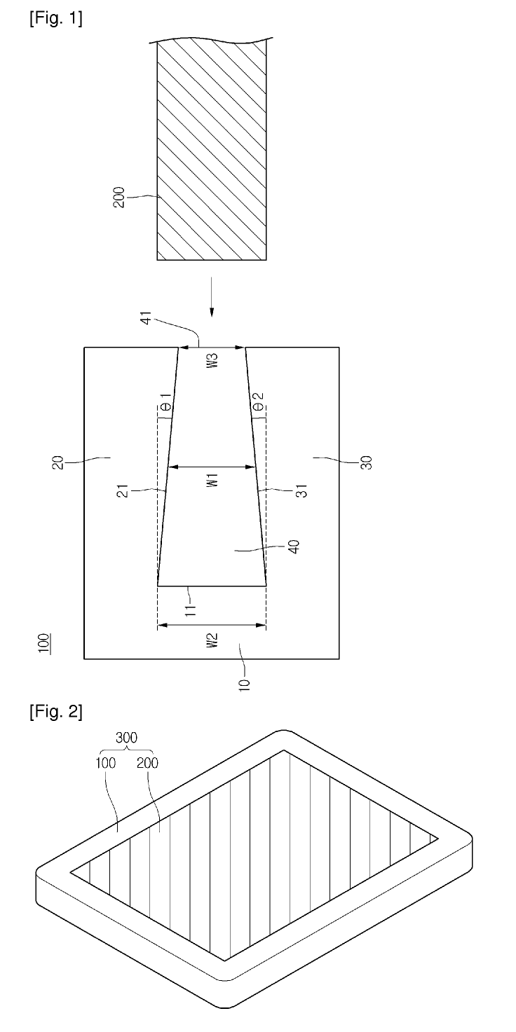

FIG. 1 is a sectional view showing a flexible frame 100 for a solar cell module according to the embodiment. The flexible frame 100 according to the embodiment not only has high adhesive strength, but also strong durability.

The flexible frame 100 may include an insulating elastic material. In detail, the flexible frame 100 may include elastic polymer material. In more detail, the flexible frame 100 may include silicon-based resin or urethane-based resin. In still more detail, the flexible frame 100 may include material selected from the group consisting of silicon rubber, PC (Poly Carbonate), PVC (Poly Vinyl Chloride), poly urethane, and the combination thereof, but the embodiment is not limited thereto. For example, the silicon rubber may include fluorine-added silicon rubber, but the embodiment is not limited thereto.

As described above, the flexible frame 100 according to the embodiment is formed in a band type by using elastic material, so that the flexible frame 100 can be simply coupled with the solar cell module, and the delamination of the flexible frame 100 can be prevented after the flexible frame 100 has been coupled with the solar cell module 20. Accordingly, the infiltration of moisture (H₂O) or oxygen (O₂) into the solar cell module 20 can be more minimized. In addition, since the flexible frame 100 includes the above material, even though the solar cell module is coupled with the flexible frame 100, a light-weight solar cell apparatus can be fabricated.

Referring to FIG. 1, the flexible frame 100 for the solar cell module 20 according to the embodiment includes a first support part 10, a second support part 20, a third support part 30, and an insertion groove 40.

The first support part 10 includes insulating elastic material as described above. In addition, the first support part 10 includes a first inner lateral side 11 directly making contact with a lateral side of the solar cell module 200 if the solar cell module 200 is inserted into the flexible frame 100. For example, the first inner lateral side 11 may have a width of about 0.5 mm to about 2.5 mm. In more detail, the first inner lateral side 11 may have a width of about 2.5 mm, but the embodiment is not limited thereto.

The second support part 20 extends toward an inner side from one end of the first support part 10. The term “inner side” used in the detailed description refers to a surface of the frame into which the solar cell module is inserted. Accordingly, the term “outer side” used in the detailed description refers to a surface of the frame into which the solar cell module is not inserted, that is, a surface of the frame exposed to external moisture or external air.

In more detail, the second support part 20 may extend toward the inner side from an upper end of the first support part 10. The second support part 20 may cross the first support part 10 substantially perpendicularly to the first support part 10.

In addition, the second support part 20 includes a second inner lateral side 21 making contact with a top surface of the solar cell module 200. The second inner lateral side 21 may have an inclined angle of about 5° to about 20° with respect to a horizontal surface. In addition, the second support part 20 may be curved or bent, but the embodiment is not limited thereto.

The third support part 30 extends toward the inner side from an opposite end of the first support part 10. In more detail, the third support part 30 may extend toward the inner side from a lower end of the first support part 10. Accordingly, the third support part 30 may cross the first support part 10 substantially perpendicular to the first support part 10. In addition, the third support part 30 may be provided in opposition to the second support part 20.

The third support part 30 includes a third inner lateral side 31 making contact with a bottom surface of the solar cell module 200. The third inner lateral side 31 may have an inclined angle of about 5° to about 20° with respect to a horizontal surface. In addition, the third support part 30 may be curved or bent, but the embodiment is not limited thereto.

Meanwhile, although the embodiment has been described in that the first to third support parts 10 to 30 are separately formed from each other, but the embodiment is not limited thereto. In other words, the first to third support parts 10 to 30 may be integrally formed with each other.

The insertion groove 40 is formed between the second and third support parts 20 and 30. In more detail, the insertion groove 40 is surrounded by the first to third support parts 10 to 30. In more detail, the insertion groove 40 may be surrounded by the first inner lateral surface 11, the second inner lateral surface 21, and the third inner lateral surface 31. In other words, the insertion groove 40 is surrounded by the first to third inner lateral sides 11 to 31 so that the insertion groove 40 may have a substantially C shape, or a substantially U shape.

The insertion groove 40 includes an opening 41. The solar cell module 200 may be introduced into the insertion groove 40 through the opening 41.

In more detail, the opening 41 is formed at a region without the first to third inner lateral sides 11 to 31. For example, the opening 41 may face the first inner lateral side 11.

Referring to FIG. 1, a width W1 of the insertion groove 40 is narrowed in a direction away from the first support part 10 is increased. In more detail, the width W1 of the insertion groove 40 is narrowed from the first inner lateral side 11 toward the opening 41.

In other words, as shown in FIG. 1, the second and third inner lateral sides 21 and 31 defining the insertion groove 40 may be inclined with respect to a horizontal surface. For example, a first inclination angle θ1 between the second inner lateral side 21 and the horizontal surface may be in the range of about 5° to about 20°, but the embodiment is not limited thereto. In addition, a second inclination angle between the third inner lateral side 31 and the horizontal surface may be in the range of about 5° to about 20°, but the embodiment is not limited thereto. In addition, the first inclination angle θ1 may be equal to or different from the second inclination angle θ2.

Therefore, the widths W3 and W2 of the opening 41 and the first inner lateral side 11, which face each other, may be different from each other. In other words, the width W3 of the opening 41 may be narrower than the width W3 of the first inner lateral side 11. For example, the width W3 of the opening 41 to the width W2 of the first inner lateral side 11 may be in the range of about 1:1.1 to about 1:1.5. In more detail, the width W3 of the opening 41 to the width W2 of the first inner lateral side 11 may be in the range of about 1:1.15 to about 1:2, but the embodiment is not limited thereto.

Due to the above structure, the delamination of the frame 100 can be prevented even through the solar cell module 200 is coupled with the frame 100. In addition, the infiltration of moisture (H₂O) or oxygen (O₂) into the solar cell module can be more minimized.

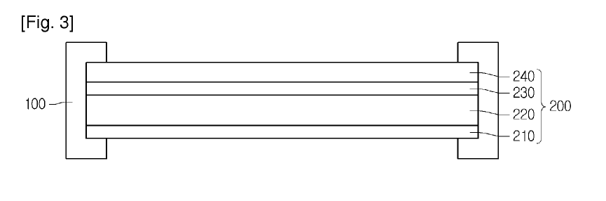

FIG. 2 is a perspective view showing the solar cell apparatus according to the embodiment. FIG. 3 is a sectional view showing the solar cell apparatus according to the embodiment. Hereinafter, the solar cell apparatus will be described by making reference to the above description of the flexible frame for the solar cell module.

As shown in FIG. 2, the flexible frame 100 surrounds the lateral sides of the solar cell module 200. In more detail, the flexible frame 100 surrounds four lateral sides of the solar cell module 200. In other words, the solar cell apparatus 300 may be fabricated by inserting the solar cell module 200 into the flexible frame 100 having a band shape.

Referring to FIG. 3, the solar cell apparatus according to the embodiment includes the solar cell module 200 and the flexible frame 100 having the insertion groove 40 including the opening 41 into which the solar cell module 200 is introduced. In this case, the width of the insertion groove 40 is narrowed toward the opening 41 as described above.

Referring to FIG. 3, the solar cell module 200 includes a plurality of solar cells 220 provided on a support substrate 210, a polymer resin layer 230 provided on the solar cells 220, and a protective panel 240 provided on the polymer resin layer 230.

The support substrate 210 has a plate shape and supports the solar cells 220, the polymer resin layer 230, and the protective panel 240.

The support substrate 210 may be a rigid panel or a flexible panel. In addition, the support substrate 210 may include an insulator. For example, the support substrate 210 may include a glass substrate, a plastic substrate, or a metallic substrate. In more detail, the support substrate 210 may include a soda line glass substrate. In addition, the support substrate 210 may include a ceramic substrate including alumina, stainless steel, or flexible polymer.

The solar cells 220 are formed on the support substrate 210. The solar cells 220 include a plurality of cells C1, C2, C3, . . . , and Cn. The cells C1, C2, C3, . . . , and Cn are electrically connected to each other. Accordingly, the solar cell 220 can convert solar energy into electrical energy.

For example, the cells C1, C2, C3, . . . , and Cn may be connected to each other in series, but the embodiment is not limited thereto. In addition, the cells C1, C2, C3, . . . , and Cn extend in one direction while being parallel to each other.

The solar cell 300 may include a solar cell including a group I-III-IV semiconductor compound such as a CIGS-based solar cell, a silicon-based solar cell, or a dye-sensitized solar cell, but the embodiment is not limited thereto.

In more detail, the solar cell 220 may include a solar cell including a group I-III-IV semiconductor compound. In this case, the solar cell 220 may include a back side electrode layer on the support substrate 210, a light absorbing layer on the back side electrode layer, a buffer layer on the light absorbing layer, a high resistance buffer layer on the buffer layer, and a front side electrode layer on the high resistance buffer layer.

The polymer resin layer 230 is provided on the solar cells 220. In more detail, the polymer resin layer 230 is interposed between the solar cells 220 and the protective panel 240. For example, the polymer resin layer 230 may directly make contact with the top surface and/or the lateral side of the solar cell 220. The polymer resin layer 230 cannot only improve adhesive strength between the solar cells 220 and the protective panel 240, but also protect the solar cells 220 from external shock.

The polymer resin layer 230 may be transparent and flexible. For example, the polymer resin layer 230 may include transparent acrylic-based materials, melamine, polystyrene, epoxy, polyvinyl butyral (PVB), or ethylene vinyl acetate (EVA). In more detail, the polymer resin layer 30 may include an EVA film, but the embodiment is not limited thereto.

The protective panel 240 is provided on the polymer resin layer 230. The protective panel 240 protects the solar cells 220 from external physical shock and/or foreign matters. The protective panel 240 is transparent, for example, may include tempered glass. In this case, the tempered glass may include lower iron tempered glass representing low iron contents.

The flexible frame 100 surrounds the solar cell module 200. In more detail, the flexible frame 100 may surround the support substrate 210 to the protective panel 240.

As described above, the solar cell apparatus 300 according to the embodiment does not require a process of coating a sealing agent on the lateral sides of the solar cell module 200 before the solar cell module 200 is coupled with the frame 100. Accordingly, the manufacturing process for the solar cell apparatus 300 can be simplified, so that the manufacturing cost can be reduced.

In addition, the flexible frame 200 according to the embodiment can prevent the delamination of the frame by using the insulating elastic material as described above. Accordingly, the infiltration of the moisture (H₂O) or the oxygen (O₂) into the solar cell module can be minimized. In addition, since the flexible frame 200 can perform a frame function as well as a function of a sealing agent used according to the related art, an additional frame is not required.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A flexible frame for a solar cell module, the flexible frame comprising:
a first support part;
a second support part extending inwardly from one end of the first support part;
a third support part extending inwardly from an opposite end of the first support part; and
an insertion groove defined by the first to third support parts to receive the solar cell module,
wherein a width of the insertion groove is narrowed in a direction away from the first support part.

2. The flexible frame of claim 1, wherein the first support part includes a first inner lateral side making contact with a lateral side of the solar cell module, the second support part includes a second inner lateral side making contact with a top surface of the solar cell module, and the third support part includes a third inner lateral side making contact with a bottom surface of the solar cell module.

3. The flexible frame of claim 2, wherein the second inner lateral side is inclined with respect to a horizontal surface, and a first inclination angle between the second inner lateral side and the horizontal surface is in a range of about 5° to about 20°.

4. The flexible frame of claim 2, wherein the third inner lateral side is inclined with respect to a horizontal surface, and a second inclination angle between the third inner lateral side and the horizontal surface is in a range of about 5° to about 20°.

5. The flexible frame of claim 2, wherein the second inner lateral side is inclined with respect to a horizontal surface, and a first inclination angle between the second inner lateral side and the horizontal surface is in a range of about 5° to about 20°,
wherein the third inner lateral side is inclined with respect to the horizontal surface, and a second inclination angle between the third inner lateral side and the horizontal surface is in a range of about 5° to about 20°, and
wherein the first inclination angle is equal to or different from the second inclination angle.

6. The flexible frame of claim 2, wherein each of the second and third inner lateral sides is bent or curved.

7. The flexible frame of claim 2, wherein the first inner lateral side has a width of about 0.5 mm to about 2.5 mm.

8. The flexible frame of claim 2, wherein the insertion groove includes an opening through which the solar cell module is introduced, and a ratio of a width of the opening to a length of the first inner lateral side is 1:1.1 to 1:5.

9. The flexible frame of claim 1, wherein the flexible frame for the solar cell module includes an insulating elastic material.

10. The flexible frame of claim 9, wherein the insulating elastic material includes a material selected from the group consisting of silicon rubber, PC (Poly Carbonate), PVC (Poly Vinyl Chloride), poly urethane, and the combination thereof.

11. A solar cell apparatus comprising:
a solar cell module; and
a flexible frame including an insertion groove having an opening through which the solar cell module is introduced, wherein a width of the insertion groove is narrowed toward the opening.

12. The solar cell apparatus of claim 11, wherein the solar cell module comprises:
a plurality of solar cells on a support substrate;
a polymer resin layer on the solar cells; and
a protective panel on the polymer resin layer.

13. The solar cell apparatus of claim 11, wherein the flexible frame includes an insulating elastic material.

14. The solar cell apparatus of claim 13, wherein the flexible frame includes a material selected from the group consisting of PC (Poly Carbonate), PVC (Poly Vinyl Chloride), poly urethane, and the combination thereof.

15. The solar cell apparatus of claim 11, wherein the flexible frame comprises:
a first support part including a first inner lateral side making contact with one lateral side of the solar cell module;
a second support part extending inwardly from one end of the first support part and including a second inner lateral side making contact with a top surface of the solar cell module; and
a third support part extending inwardly from an opposite end of the first support part and including a third inner lateral side making contact with a bottom surface of the solar cell module.

16. The solar cell apparatus of claim 15, wherein the insertion groove is defined by the first to third support parts.

17. The solar cell apparatus of claim 15, wherein the second inner lateral side is inclined with respect to a horizontal surface, and a first inclination angle between the second inner lateral side and the horizontal surface is in a range of about 5° to about 20°.

18. The solar cell apparatus of claim 15, wherein the third inner lateral side is inclined with respect to a horizontal surface, and a second inclination angle between the third inner lateral side and the horizontal surface is in a range of about 5° to about 20°.

19. The solar cell apparatus of claim 15, wherein the second inner lateral side is inclined with respect to a horizontal surface, and a first inclination angle between the second inner lateral side and the horizontal surface is in a range of about 5° to about 20°, wherein the third inner lateral side is inclined with respect to the horizontal surface, and a second inclination angle between the third inner lateral side and the horizontal surface is in a range of about 5° to about 20°, and wherein the first inclination angle is equal to or different from the second inclination angle.

20. The solar cell apparatus of claim 15, wherein the first inner lateral side has a width of about 0.5 mm to about 2.5 mm.
